(19) United States
(12) Patent Application Publication
(10) Pub. No.: US 2014/0048785 A1
(43) Pub. Date: Feb. 20, 2014

(54) OPTOELECTRONIC COMPONENT AND USE OF A COPPER COMPLEX AS DOPANT FOR DOPING A LAYER

(71) Applicants: Karsten Heuser, Erlangen (DE); Silke Scharner, Regensburg (DE); Stefan Seidel, Wenzenbach (DE)

(72) Inventors: Karsten Heuser, Erlangen (DE); Silke Scharner, Regensburg (DE); Stefan Seidel, Wenzenbach (DE)

(73) Assignee: OSRAM OPTO SEMICONDUCTORS GMBH, Regensburg (DE)

(21) Appl. No.: 14/004,920

(22) PCT Filed: Mar. 1, 2012
(86) PCT No.: PCT/EP2012/053549

§ 371 Date: Sep. 13, 2013

(30) Foreign Application Priority Data
Apr. 8, 2011 (DE) 102011007052.4

(51) Int. Cl. H01L 51/50; H01L 51/42

(52) U.S. Cl. CPC H01L 51/5028; H01L 51/4206
USPC 257/40

(57) ABSTRACT

An optoelectronic component includes: a wet-chemically processed hole injection layer; and an additional layer doped with a dopant and adjacent to the wet-chemically processed hole injection layer, the dopant comprising a copper complex having at least one ligand with the chemical structure according to formula I in which E1 and E2 are each independently one of the following elements: sulfur, oxygen or selenium, and R is selected from the group of: hydrogen or substituted or unsubstituted, branched, linear or cyclic hydrocarbons.

### RELATED APPLICATIONS

The present application is a national stage entry according to 35 U.S.C. §371 of PCT application No.: PCT/EP2012/053549 filed on Mar. 1, 2012, which claims priority from German application No.: 10 2011 007 052.4 filed on Apr. 8, 2011.

### TECHNICAL FIELD

Various embodiments relate to an optoelectronic component and to use of a copper complex as a dopant for doping a layer.

### BACKGROUND

An optoelectronic component is designed for conversion of electrical energy to electromagnetic radiation, for example to visible light, or for the inverse operation. In each case, reference may be made to an emitter device or to a detector device. One example of an electromagnetic component as an emitter device is a light-emitting device, for example a light-emitting diode (LED). The device typically includes electrodes between which is arranged an active zone. An electrical current can be supplied via the electrodes to the light-emitting device and is converted in the active zone to optical energy, i.e. electromagnetic radiation. The optical energy is emitted from the light-emitting device via a radiation emission surface.

A particular light-emitting device is the organic light-emitting diode (OLED). An OLED has an organic layer in the active layer in order to convert electrical energy to electromagnetic radiation. When the OLED is connected via the electrodes to a power source, different charge carrier types are injected into the organic layer. Positive charge carriers, also referred to as holes, migrate from the anode to the cathode through the organic layer, while electrodes migrate through the organic layer from the cathode to the anode. This forms excited states in the form of electron-hole pairs, called excitons, in the organic layer, and these break down with emission of electromagnetic radiation.

A further example of an optoelectronic component is the detector device, in which optical radiation is converted to an electrical signal or to electrical energy. Such an optoelectronic component is, for example, a photodetector or solar cell. A detector device also has an active layer arranged between electrodes. The detector device has a radiation input side, through which electromagnetic radiation, for example light, infrared radiation or ultraviolet radiation, enters the detector device and is conducted to the active layer. In the active layer, an exciton is produced under the action of the radiation, and this is divided into an electron and a hole in an electrical field. Thus, an electrical signal or an electrical charge is generated and provided to the electrodes.

In all cases, a high efficiency of the conversion of electrical energy to electromagnetic radiation or for the inverse operation is desirable.

OLEDs can be produced with good efficiency and lifetime by means of a wet-chemically processed high-conductivity hole injection layer (HIL). This hole injection layer has the advantage that it is much more favorable than a thick conductivity-doped hole injection layer (HIL) and, due to the lower layer thickness, also enables a higher efficiency.

### SUMMARY

Various embodiments provide an optoelectronic component having a wet-chemically processed hole injection layer which has a high efficiency combined with adequate process stability.

The various configurations of the embodiments described hereinafter apply in the same way, if usable analogously, to the optoelectronic component and to the use of the copper complex in an organic layer structure.

Various working examples provide an optoelectronic component including:
a wet-chemically processed hole injection layer; and an additional layer doped with a dopant and adjacent to the wet-chemically processed hole injection layer, the dopant including a copper complex having at least one ligand with the chemical structure according to formula I:

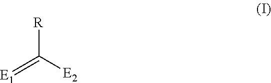

in which E₁ and E₂ are each independently one of the following elements: sulfur, oxygen or selenium, and R is selected from the group of: hydrogen or substituted or unsubstituted, branched, linear or cyclic hydrocarbons.

It has been found that replacement of the thick conductivity-doped hole injection layer by a wet-chemically processed hole injection layer reduces process stability which can be manifested in scatter in the electrical IV characteristic.

Through the various working examples, it is possible to increase the transparency of the optoelectronic component. In addition, the optoelectronic component is producible inexpensively and may have an increased lifetime.

A further advantage of the organic copper-containing dopant may be regarded as being the low vaporization temperature thereof under vacuum conditions of only about 200° C. The inorganic p dopants have significantly higher vaporization temperatures, as a result of which the use thereof is only enabled by the use of particularly high-temperature vaporization sources.

In various working examples, an additional layer is provided, for example a layer doped with a dopant. Such an additional layer, for example a thin layer, clearly functions as a kind of hole reservoir, and compensates for the above-detailed reduced process stability which arises in the case of use of a wet-chemically processed hole injection layer. In various working examples, the dopant may be a p dopant. For the doping, it is possible to use inorganic materials (for example V₂O₅, MoO₃, WO₃) or organic materials (for example F4-TCNQ) as the dopant.

In addition, in various working examples, use of such a copper complex in the additional layer achieves high hole conductivity and low absorption in the visible spectral region.

The optoelectronic component may also have an organic layer structure for separation of charge carriers of a first charge type and charge carriers of a second charge type.

The organic layer structure is set up to separate charge carriers of a first charge carrier type from charge carriers of a second charge carrier type. For example, the charge carriers of the first charge carrier type are holes and the charge carriers of the second charge carrier type are electrons. One example of such a layer structure is a charge generating layer sequence (CGL).

Such a charge generating layer sequence has a p-doped layer including the above-identified copper complex as a p dopant, for example an additional layer applied to the above-described wet-chemically processed (for example high-conductivity) hole injection layer. The wet-chemically processed (for example high-conductivity) hole injection layer may be connected to an n-doped layer via a potential barrier, for example in the form of an interface or of an insulating interlayer. The copper complex has very good dopability. It improves charge carrier transport in the charge generating layer; for example, the conductivity of holes in the p-doped region is increased. Through the high conductivities and dopabilities, it is possible to achieve significant band bending in the p-doped layer close to the potential barrier. Tunneling of charge carriers through the potential barrier can thus be improved. As a result of the high conductivity, charge carriers transferred by tunneling can easily be transported out of the charge generating layer sequence. Overall, the charge generating layer sequence can thus provide a high number of freely mobile charge carriers, as a result of which a particularly high efficiency of the optoelectronic component is achieved.

A further advantage of the use of copper complexes is the easy availability of the starting materials and the safe processing of the dopants, such that it is possible to use an inexpensive and environmentally protective alternative to dopants already known.

In some embodiments, the copper complex is a copper(I) pentafluorobenzoate. This has the following structure:

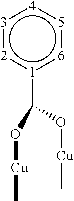

where positions 2 to 6 are occupied by a fluorination. The choice of the copper(I) pentafluorobenzoate is advantageous particularly because this complex is associated with a high hole conductivity and a low absorption in the visible spectral region. For a (4,4′,4″-tris(N-(1-naphthyl)-N-phenylamino)triphenylamine layer of thickness 100 nm which has been doped with copper(I) pentafluorobenzoate, a transmission of more than 93% above a wavelength of 420 nm was measured.

In addition, copper(I) pentafluorobenzoate is particularly suitable for processing in the course of production of an optoelectronic component. It has a vaporization temperature of only about 200° C. Other dopants used for p-doping, such as V₂O₅, MoO₃, WO₃ or F4-TCNQ (2,3,5,6-tetrafluoro-7,7,8,8-tetracyanoquino-dimethane), have a significantly higher vaporization temperature. Copper(I) pentafluorobenzoate can therefore be processed without the use of particularly high-temperature vaporization sources.

In some embodiments, the p-doped organic semiconductor layer has a doping gradient toward the n-doped organic semiconductor layer. This means that the concentration of the dopant changes over the cross section of the p-doped organic semiconductor layer. Advantageously, the doping of the p-doped organic semiconductor layer increases toward the n-doped organic semiconductor layer. Thus, mobility of holes in the p-doped organic semiconductor layer is increased specifically in the region of the interface of the n-doped organic semiconductor layer or of the interlayer. This is particularly advantageous for onward transport of charge carriers in this region. In addition, a potential barrier at the interface or the interlayer can be made particularly efficient in this way. A doping gradient can be achieved, for example, through the application of several p-doped organic semiconductor layers one on top of another. It is likewise conceivable that the supply of the dopant is altered by a suitable operation during a production process for the p-doped organic semiconductor layer, such that the layer is doped differently with increasing layer thickness. The dopant concentration may run, for example, from 0% at the interface or the side remote from the interlayer to 100% at the interface or the side facing the interlayer. In this case, a thin dopant film at the interface/interlayer is conceivable. It is additionally conceivable that different dopants are incorporated in the p-doped organic semiconductor layer, and that a variation in the conductivity or a suitable configuration of the potential barrier is thus achieved.

In various embodiments, the optoelectronic component has a layer stack including the organic layer structure. This layer stack may include at least one active layer. The active layer includes, for example, an electroluminescent material. The optoelectronic component is thus configured as a radiation-emitting device. In various embodiments, the organic layer structure is arranged between a first active layer and a second active layer. The organic layer structure especially has the function of providing intrinsic charge carriers to active layers. In various embodiments, the organic layer structure has been applied to an electrode, for example an anode contact. In this case, the organic layer structure advantageously supports passage of positive charge carriers from the anode material to organic semiconductor layers.

In various working examples, the optoelectronic component may take the form of a top emitter, of a bottom emitter or of a top and bottom emitter.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a schematic diagram of a working example of a charge generating layer;

FIG. 2 shows a schematic diagram of another working example of a charge generating layer;

FIG. 3 shows a schematic diagram of the energy levels in a charge generating layer sequence without voltage applied;

FIG. 4 shows a schematic diagram of the energy levels in the charge generating layer sequence with reverse voltage applied;

FIG. 5 shows a schematic diagram of a working example of an optoelectronic component;

FIG. 6 shows a schematic diagram of another working example of an optoelectronic component; and

FIG. 7 shows a schematic diagram of another working example of an optoelectronic component.

### DETAILED DESCRIPTION

In the detailed description which follows, reference is made to the appended drawings, which form part thereof and in which specific embodiments in which this disclosure can be executed are shown for illustration. In this regard, directional terminology, for instance “top”, “bottom”, “front”, “back”, “anterior”, “posterior”, etc. is used with reference to the orientation of the figure(s) described. Since components of embodiments can be positioned in a number of different orientations, the directional terminology serves for illustration and does not restrict it in any way whatsoever. It will be appreciated that other embodiments can be utilized and structural or logical changes can be undertaken without deviating from the scope of protection of this disclosure. It will be appreciated that the features of the various illustrative embodiments described herein can be combined with one another, unless specifically stated otherwise. The detailed description which follows should therefore not be interpreted in restrictive manner, and the scope of protection of this disclosure is defined by the appended claims.

In the context of this description, the terms “connected”, “attached” and “coupled” are used to describe either a direct or indirect connection, a direct or indirect attachment and a direct or indirect coupling. In the figures, identical or similar elements are provided with identical reference numerals, if appropriate.

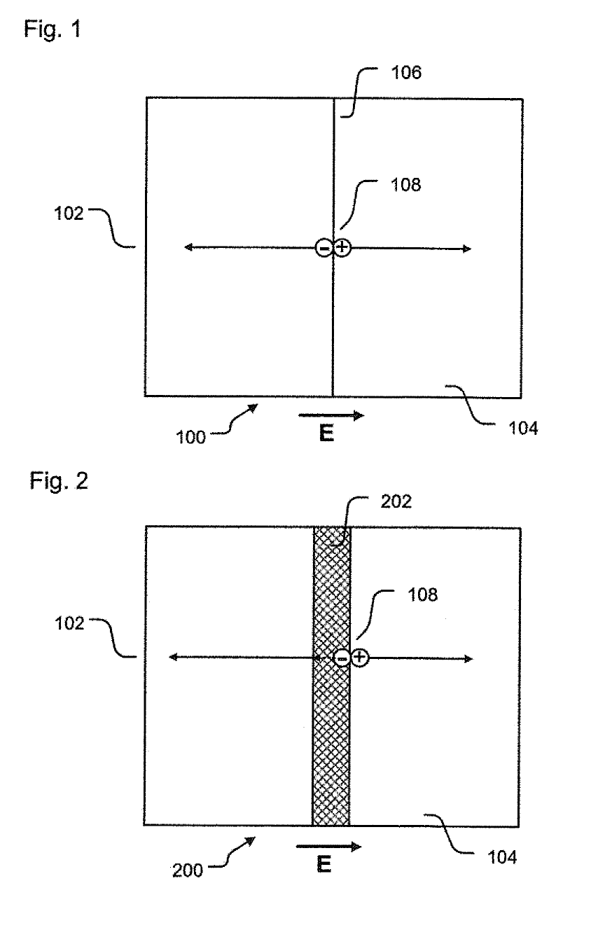

FIG. 1 and FIG. 2 show a schematic diagram of two working examples of a charge generating layer sequence 100.

The charge generating layer sequence 100 has, in different configurations, a layer sequence of doped organic and inorganic semiconductor materials.

In the working example shown in FIG. 1, the charge generating layer sequence 100 is configured as a layer sequence of an n-doped first organic semiconductor layer 102 and a p-doped second organic semiconductor layer 104.

Between the first organic semiconductor layer 102 and the second organic semiconductor layer 104 is an interface 106.

At the interface 106 of the n-doped first organic semiconductor layer 102 and the p-doped second organic semiconductor layer 104, a depletion zone is formed with application of an electrical field E. As a result of quantum fluctuations, a charge carrier pair 108 can form spontaneously at the interface 106. The charge carrier pair 108 has charge carriers of different charge carrier types, for instance an electron and a hole. The electron can cross the potential barrier of the interface 106 from the p-doped second organic semiconductor layer 104 by tunneling and thus occupy a free state in the n-doped semiconductor layer 102. In the p-doped second semiconductor layer 104, an unoccupied state in the form of a hole remains at first. This fluctuation can thus be described such that a charge carrier pair 108 with charge carriers of different charge carrier types forms spontaneously at the interface 106. A tunneling operation separates the charge carriers. Under the action of the electrical field E, the charge carriers, according to the charge carrier type, migrate in the direction of the anode 102 or of the cathode 104. Recombination of the charge carriers by a further tunneling operation is thus prevented by the charge carrier transport to the electrodes brought about by the electrical field E.

In the working example of a charge generating layer sequence 200 shown in FIG. 2, a suitable interlayer 202 is arranged as a potential barrier between the first organic semiconductor layer 102 and the second organic semiconductor layer.

The interlayer 202 includes, for example, a material such as CuPc (copper phthalocyanine). With the aid of the interlayer 202, the charge generating layer sequence 200 can be stabilized in terms of dielectric strength. In addition, it is possible by means of the interlayer 202 to prevent diffusion of dopants from one organic intermediate layer into the other, or chemical reaction between the two organic semiconductor layers or the dopants thereof. Finally, it is possible by means of the interlayer 202 to configure the potential barrier, especially the width of the potential barrier, between the n-doped first organic semiconductor layer 102 and the p-doped second organic semiconductor layer 104. It is thus possible to influence, for example, the strength of any tunneling current which arises through quantum fluctuations.

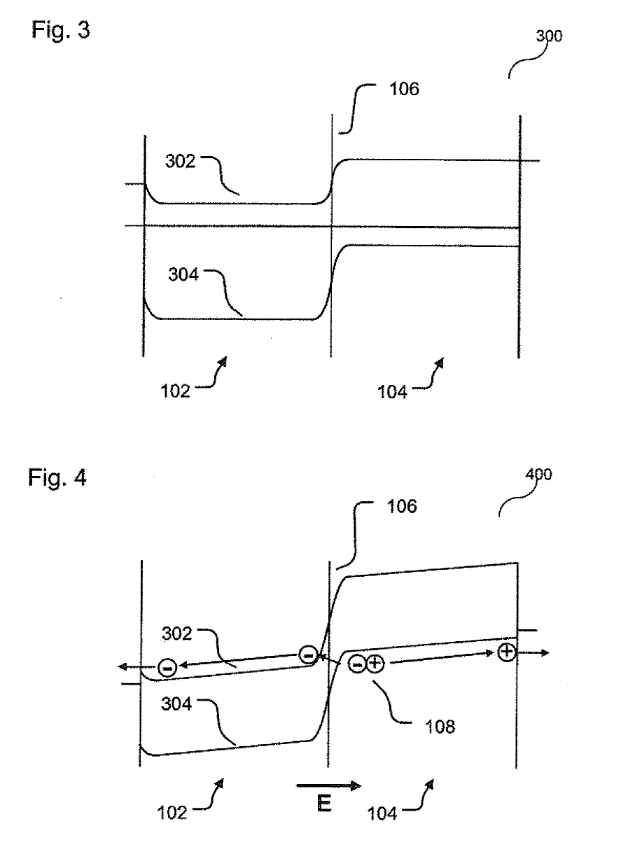

FIG. 3 shows a schematic diagram 300 of the energy levels in the charge generating layer sequence 100 without electrical voltage applied. The charge generating layer sequence 100 includes the n-doped first organic semiconductor layer 102 and the p-doped second organic semiconductor layer 104. The charge transport in organic semiconductors takes place essentially through hopping operations from a localized state to an adjacent, likewise localized state. FIG. 3 shows the energy levels in the first organic semiconductor layer 102 and the second organic semiconductor layer 104. Shown in each case are the lowest unoccupied molecular orbital (LUMO) energy level 302 and the highest occupied molecular orbital (HOMO) energy level 304 of the first organic semiconductor layer 102 and of the second organic semiconductor layer 104. The LUMO energy level 302 is comparable to the conduction band of an inorganic semiconductor and indicates the energy region in which electrons have very high mobility. The HOMO energy level 304 is comparable to the valence band of an inorganic semiconductor and indicates the energy region in which holes have very high mobility. Between the LUMO energy level and the HOMO energy level, an energy gap forms, which would correspond to a band gap in an inorganic semiconductor.

The first organic semiconductor layer 102 is n-doped, while the second organic semiconductor layer 104 is p-doped. Accordingly, the first organic semiconductor layer 102 has a lower LUMO energy level and a lower HOMO energy level than the second organic semiconductor layer 104. At the interface 106, the energy levels merge continuously into one another through free charge carriers or possible dipole formation. The result is band bending at the interface 106.

FIG. 4 shows a schematic diagram 400 of the energy levels in the charge generating layer sequence 100 with an electrical reverse voltage applied. The reverse voltage is associated with an electrical field E. Because of the reverse voltage, there is a shift in the energy levels in the organic semiconductor layers, in that they are inclined because of the drop in voltage over the charge generating layer sequence 100. At the interface 106, a region in which the LUMO energy level 302 of the first organic semiconductor layer 102 assumes equal values to the HOMO energy level 304 of the second organic semiconductor layer 104 thus arises. As a result of quantum fluctuations, a charge carrier pair 108 can form at the interface 106 in the HOMO energy level 304 of the second organic semiconductor layer 104. The charge carrier pair 108 consists of an electron and a hole. As a result of the band bending at the interface 108, the electron can cross the potential barrier at the interface 106 with a relatively high probability in a tunneling operation and assume a free state in the LUMO energy level 302 of the n-doped first organic semiconductor layer 102.

The remaining hole is transported out of the second organic semiconductor layer 104 away from the interface layer 106 by the electrical field E. The electron in the first organic semiconductor layer is transported away from the interface layer 200 as a result of the falling LUMO energy level. The outcome is that, with application of a reverse voltage, because of intrinsic excitation at the charge generating layer sequence 100, additional free charge carriers are provided.

It is conceivable that a suitable interlayer 202 as a potential barrier is arranged between the first organic semiconductor layer 102 and the second organic semiconductor layer to increase or configure the tunneling current. The interlayer 202 includes, for example, a material such as CuPc (copper phthalocyanine). With the aid of the interlayer 202, the charge generating layer sequence 100 can be stabilized in terms of dielectric strength. In addition, the interlayer can be used to prevent diffusion of dopants from one organic semiconductor layer into the other, or a chemical reaction between the two organic semiconductor layers or dopants thereof. Finally, the interlayer can be used to configure the potential barrier, especially the width of the potential barrier, between the n-doped organic semiconductor layer 102 and the p-doped organic semiconductor layer 104. It is thus possible, for example, to influence the strength of a tunneling current which arises through quantum fluctuations.

On the basis of the described function of the charge generating layer sequence 100, it can also be referred to as an organic layer for separation of charge carriers, or as a CGL. Studies regarding the charge generating layer sequence 100 are known, for example, from document [1] and document [2], which are hereby incorporated by reference into the disclosure of the present application.

The first organic semiconductor layer 102 is n-doped. For the n-doping it is possible to use metals with a low work function, for example cesium, lithium or magnesium. Compounds containing these metals are likewise suitable as an n-dopant, for example Cs₂CO₃, CsF or LiF. These dopants may be incorporated in or introduced into a matrix material. An example of a suitable matrix material is TPBi (1,3,5-tris(1-phenyl-1H-benzimidazol-2-yl)benzene).

The second organic semiconductor layer 104 may be p-doped, for example with a dopant concentration within a range from about 1% to about 30%, for example within a range from about 1% to about 15%, for example within a range from about 2% to about 8%.

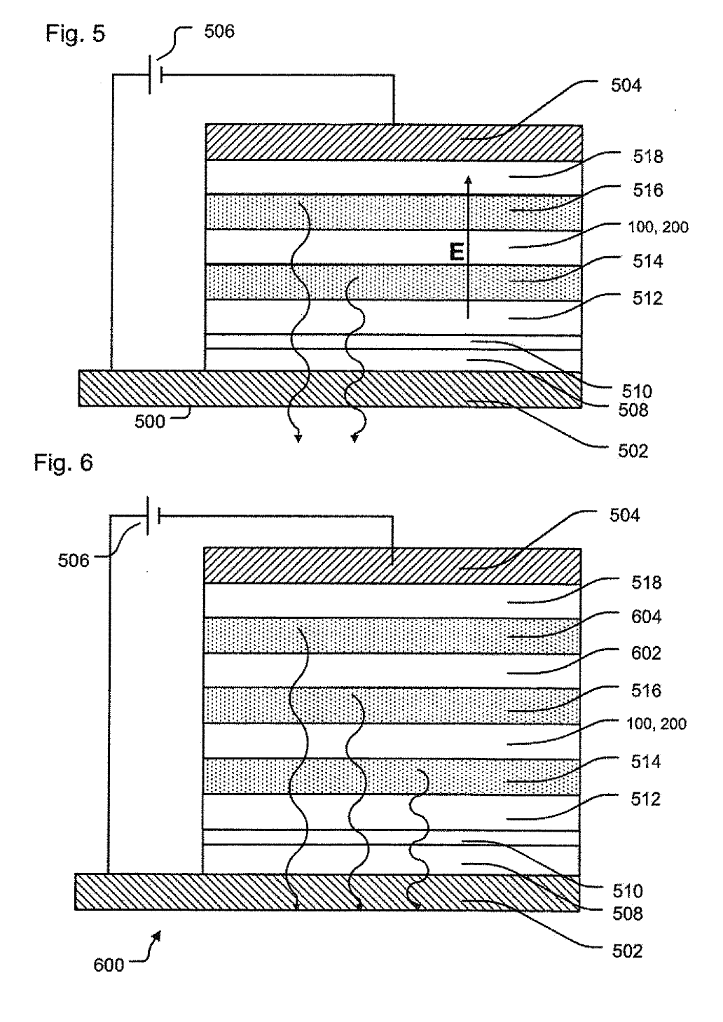

FIG. 5 shows the schematic diagram of a working example of an optoelectronic component 500 with a charge generating layer sequence 100, 200. It should be pointed out that the charge generating layer sequence 100, 200 is optional in the optoelectronic components described hereinafter.

The optoelectronic component 500 has an anode 502 and a cathode 504. The anode 502 and the cathode 504 serve as electrodes for the optoelectronic component 500. They may be connected to an external power source 506, for example to a battery or to an accumulator. Between the anode 502 and the cathode 504 is arranged a layer stack of organic and/or inorganic semiconductor materials. The anode 502 and the cathode 504 each include a material of good conductivity, which can be selected in terms of the optical properties thereof. For example, the anode 502 and/or the cathode 504 may consist of a transparent material including a metal oxide, for instance an indium tin oxide (ITO), and/or a transparent conductive polymer. It is likewise possible for at least one of the anode 502 and cathode 504 to consist of a high-conductivity reflective material including, for example, a metal, for instance aluminum, silver, platinum, copper or gold, or a metal alloy.

Positive charge carriers (holes) are injected into the layer stack via the anode 502, while negative charge carriers (electrons) are injected into the layer stack via the cathode 504. At the same time, there is an electrical field E between the anode 502 and the cathode 504. The effect of the electrical field E is that holes injected from the anode 502 migrate through the layer stack in the direction of the cathode 504. Electrons injected from the cathode 504 migrate under the influence of the electrical field E in the direction of the anode 502.

The layer stack has a number of different functional layers.

Directly applied or arranged on the anode 502 in various working examples is a wet-chemically processed (also referred to hereinafter as liquid-processed) (high-conductivity) hole injection layer (HIL) 508. The wet-chemically processed hole injection layer 508 has a conductivity within a range from about 10⁻⁷ S/cm to about 10⁻¹ S/cm, for example within a range from about 10⁻⁶ S/cm to about 10⁻¹ S/cm. In various working examples, the wet-chemically processed hole injection layer 508 has a layer thickness within a range from about 50 nm to about 150 nm, for example with a layer thickness within a range from about 60 nm to about 120 nm, for example with a layer thickness within a range from about 70 nm to about 100 nm. On the wet-chemically processed hole injection layer 508, in various working examples, is provided an additional layer 510 as a process stabilization layer, for example having a layer thickness within a range from about 1 nm to about 20 nm, for example a layer thickness within a range from about 3 nm to about 10 nm.

The wet-chemically processed hole injection layer 508 can be dissolved in solvents, and spun, printed or sprayed onto the anode 502, according to the desired operation. The wet-chemically processed hole injection layer 508 may, for example, include or be formed from PEDOT:PSS.

In various working examples, the wet-chemically processed hole injection layer 508 is provided in order to balance out any unevenness in the surface of the anode 502.

The additional layer 510 may be p-doped. A dopant provided for the additional layer 510 in various working examples is a copper complex. In various working examples, the additional layer 510 is doped with the dopant with a dopant concentration within a range from about 1% to about 20%, for example within a range from about 1% to about 15%, for example within a range from about 2% to about 8%. The following materials may be used as part of the matrix material of the additional layer 110: NPB (N,N′-bis(1-naphthyl)-N,N′-bis(phenyl)benzidine), β-NPB (N,N′-bis(naphthalen-2-yl)-N,N′-bis(phenyl)benzidine), TPD (N,N′-bis(3-methylphenyl)-N,N′-bis(phenyl)benzidine), N,N′-bis(1-naphthyl)-N,N′-bis(phenyl)-2,2-dimethylbenzidine, spiro-TPD (N,N′-bis(3-methylphenyl)-N,N′-bis(phenyl)-9,9-spirobifluorene), spiro-NPB (N,N′-bis(1-naphthyl)-N,N′-bis(phenyl)-9,9-spirobifluorene), DMFL-TPD (N,N′-bis(3-methylphenyl)-N,N′-bis(phenyl)-9,9-dimethylfluorene, DMFL-NPB (N,N′-bis(1-naphthyl)-N,N′-bis(phenyl)-9,9-dimethylfluorene), DPFL-TPD (N,N′-bis(3-methylphenyl)-N,N′-bis(phenyl)-9,9-diphenylfluorene), DPFL-NPB (N,N″bis(naphth-1-yl)-N,N′-bis(phenyl)-9,9-diphenylfluorene), Sp-TAD (2,2′,7,7′-tetrakis(N,N-diphenylamino)-9,9′-spirobifluorene), TAPC (di[4-(N,N-ditolylamino)phenyl]cyclohexane), spiro-TTB (2,2′,7,7′-tetra(N,N-ditolyl)aminospirobifluorene), BPAPF (9,9-bis[4-(N,N-bisbiphenyl-4-ylamino)phenyl]-9H-fluorene), spiro-2NPB (2,2′,7,7′-tetrakis[N-naphthyl(phenyl)amino]-9,9-spirobifluorene), spiro-5 (2,7-bis[N,N-bis(9,9-spirobifluoren-2-yl)amino]-9,9-spirobifluorene), 2,2′-spiro-DBP (2,2′-bis[N,N-bis(biphenyl-4-yl)amino]-9,9-spirobifluorene), PAPB (N,N-bis(phenanthren-9-yl)-N,N′-bis(phenyl)benzidine), TNB (N,N,N′,N′-tetranaphthalen-2-ylbenzidine), spiro-BPA (2,2′-bis(N,N-diphenylamino)-9,9-spirobifluorene), NPAPF (9,9-bis[4-(N,N-bisnaphthylamino)phenyl]-9H-fluorene), NPBAPF (9,9-bis[4-(N,N′-bisnaphth-2-yl-N,N′-bisphenylamino)phenyl]-9H-fluorene), TiOPC (titanium oxide phthalocyanine), CuPC (copper phthalocyanine), F4-TCNQ (2,3,5,6-tetrafluoro-7,7,8,8-tetracyanoquino-dimethane), m-MTDATA (4,4′,4″-tris(N-3-methylphenyl-N-phenylamino)triphenylamine), 2T-NATA (4,4′,4″-tris(N-(naphthalen-2-yl)-N-phenylamino)triphenylamine), 1-TNATA (4,4′,4″-tris(N-1-naphthyl)-N-phenylamino)triphenylamine), NATA (4,4′,4″-tris(N,N-diphenylamino)triphenylamine), PPDN (pyrazino[2,3-f][1,10]phenanthro-line-2,3-dicarbonitrile), MeO-TPD (N,N,N′,N′-tetrakis-(4-methoxyphenyl)benzidine), MeO-spiro-TPD (2,7-bis-[N,N-bis(4-methoxyphenyl)amino]-9,9-spirobifluorene), 2,2′-MeO-spiro-TPD (2,2′-bis[N,N-bis(4-methoxyphenyl)-amino]-9,9-spirobifluorene), β-NPP (N,N′-di(naphthalen-2-yl)-N,N′-diphenylbenzene-1,4-diamine), NTNPB (N,N′-diphenyl-N,N′-di[4-(N,N-ditolylamino)phenyl]benzidine) or NPNPB (N,N′-diphenyl-N,N′-di[4-(N,N-diphenylamino)-phenyl]benzidine).

The p dopant used for the additional layer 510 in various working examples is a copper complex having at least one ligand having the chemical structure of the formula I:

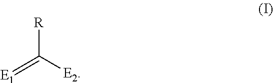

E₁ and E₂ are each independently one of the following elements: oxygen, sulfur or selenium. R is selected from the group of: hydrogen or substituted or unsubstituted, branched, linear or cyclic hydrocarbons.

The abovementioned copper complex, in relation to the matrix material of the additional layer 510, is a metallo-organic acceptor compound. It serves as a p dopant. This copper complex may be an isolated molecule. Frequently, the copper complex will be bonded via chemical bonds to molecules of the matrix material, for example by virtue of molecules of the matrix material as ligands forming part of the copper complex. Typically, the copper atom forms complexes with organic ligands. The organic ligands may form suitable functional groups, such that a bond to an oligomer or a polymer is enabled.

The copper complex may include a monodentate, tridentate or tetradentate ligand. More particularly, it may contain one or more groups C(=E₁)E₂ where at least one or more than one of the donor atoms E₁ and E₂ in the ligands and the copper atoms form a complex.

This C(=E₁)E₂ group typically has a negative charge. Non-deprotonated carboxylic acids or homologs thereof may likewise also serve as ligands of the copper complex. In general, the ligand of the copper complex contributes negative charge to the complex, for example through one negative charge per carboxyl group or per carboxyl group homolog.

If no molecules in the matrix material form bonds with the copper atoms, the copper complex is a homoleptic complex in which solely ligands form a complex with the central copper atom. Often, such a complex has a rectangular or linear molecule geometry. This is true particularly when interactions between copper atoms are negligible. If molecules from the matrix material form bonds to the central copper atom, the molecule geometry of the complex assumes the form of a pentagonal bipyramid or the complex gains square-pyramidal molecule geometry. This copper complex is usually an electrically uncharged complex.

The copper complex may be either a mononuclear copper complex or a polynuclear copper complex. In a polynuclear copper complex, the ligand may be bonded only to one copper atom or to two copper atoms. In this case, the ligand may, for example, form a bridge between two copper atoms. Should the ligand be tri- or polyvalent, it may also bond more copper atoms as a bridge. In the case of a polynuclear copper complex, copper-copper bonds may exist between two or more copper atoms. The use of polynuclear copper complexes is particularly advantageous because such a doped organic functional layer has a longer lifetime than a functional layer doped with a mononuclear copper complex. This can be explained by a destabilization of the complex in the event of charge transport by the functional layer. The effect of charge transport in the case of polynuclear copper complexes is distributed not just over one copper complex but over several.

A polynuclear copper complex may have what is called a “paddle-wheel” structure. This is true especially in the case of a copper(II) complex. Typically, a paddle-wheel structure is assumed in a complex having two metal atoms, where two copper atoms are bonded to one or more polyvalent ligands as a bridge.

Frequently, the mode of coordination of all ligands with respect to the copper atom is almost identical. Thus, with regard to the copper atoms and the ligands, at least one twofold or fourfold axis of rotation is defined by two of the copper atoms of the polynuclear copper complex. Square-planar complexes often have an at least fourfold axis of rotation, whereas linear-coordinated complexes frequently have a twofold axis of rotation.

The copper atom of a mononuclear complex or at least one copper atom of a polynuclear copper complex may have an oxidation state of +2. In such complexes, the ligands are frequently coordinated in a square-planar geometry. If the copper atom has an oxidation state of +1, the copper atom is frequently in linear coordination.

Copper complexes having a Cu(II) atom generally have higher hole conductivity than copper complexes having a Cu(I) atom. The latter have a complete d¹⁰ shell. The hole conductivity is caused primarily by the Lewis acid formed by the Cu(I) atoms. Cu(II) complexes, in contrast, have an unfilled d⁹ configuration, which causes oxidation behavior. Partial oxidation increases the hole density. However, the use of Cu(I) complexes may be advantageous because Cu(I) complexes are frequently more thermally stable than the corresponding Cu(II) complexes.

A feature common to the copper complexes described is that they are a Lewis acid. A Lewis acid is a compound which acts as an electron pair acceptor. The behavior of the copper complexes as a Lewis acid is associated with the molecules of the matrix material into which the copper complex has been incorporated as a dopant.

The molecules of the matrix material generally act as a Lewis base in relation to the Lewis-acidic copper molecules. A Lewis base is an electron pair donor.

The copper atom in the copper complex has an open, i.e. a further, coordination site. A Lewis-basic compound may bind to this coordination site, for example an aromatic ring system, a nitrogen atom or an amine component, which are present in the matrix material. This is shown by way of example in FIGS. 1 and 2:

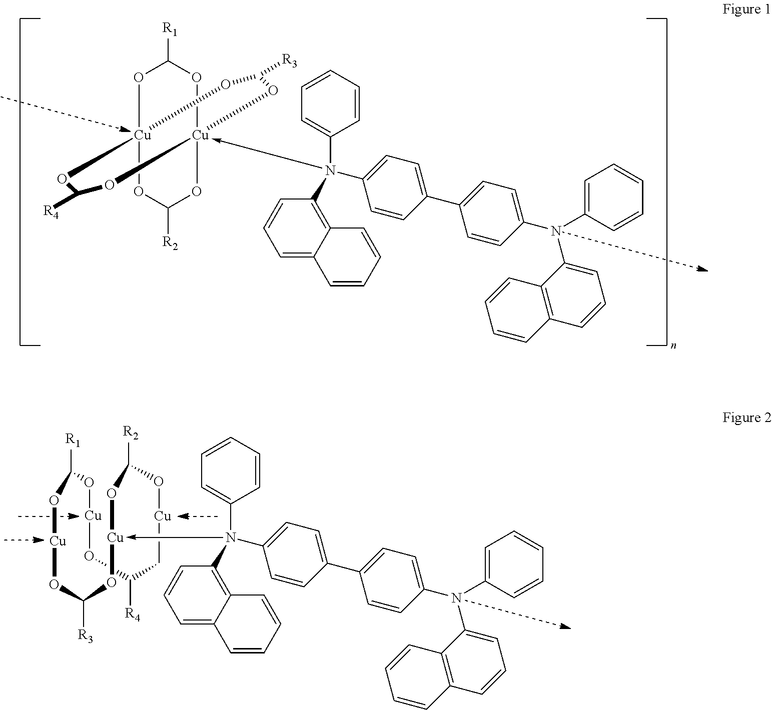

It is also possible for groups having heteroaromatic ring systems or a nitrogen atom in an amine component to coordinate to a copper atom.

The ligand which coordinates to the copper atom may have an R group which includes a substituted or unsubstituted hydrocarbon group. The hydrocarbon group may be a linear, branched or cyclic group. This may have 1-20 carbons. For example, it is a methyl or ethyl group. It may also have fused substituents, such as decahydronaphthyl, adamantyl, cyclohexyl or partly or fully substituted alkyl groups. The substituted or unsubstituted aromatic groups are, for example, phenyl, biphenyl, naphthyl, phenanthryl, benzyl or a heteroaromatic radical, for example a substituted or unsubstituted radical which may be selected from the heterocycles in FIG. 3:

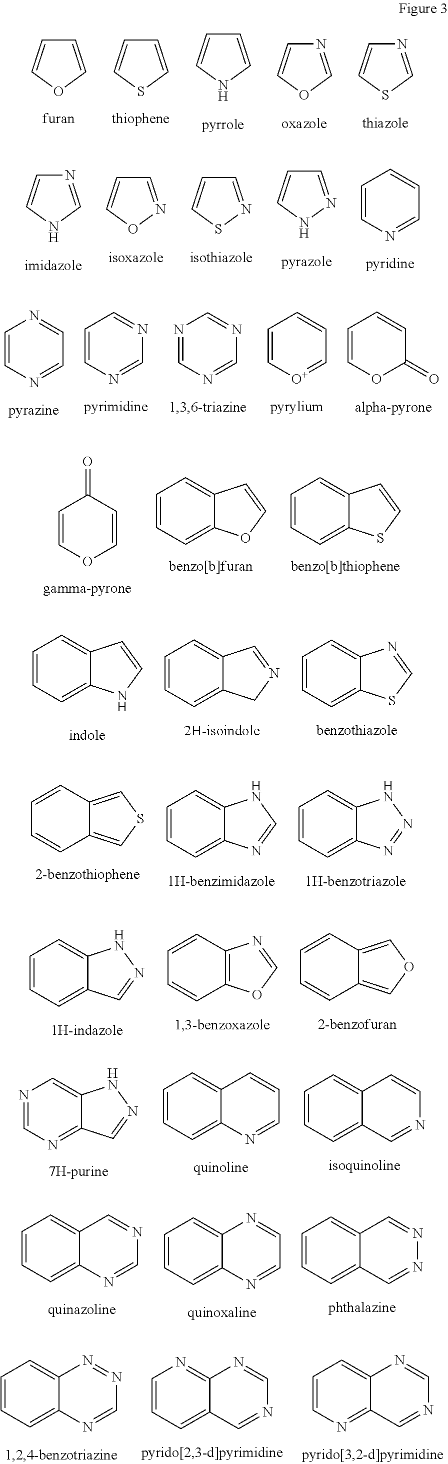

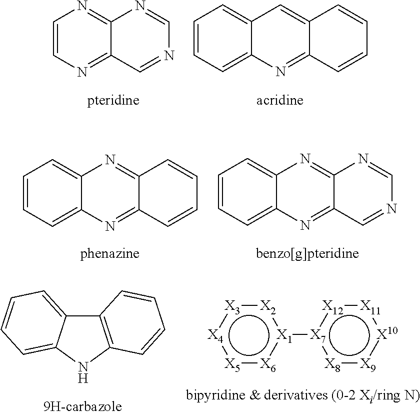

The ligand which coordinates to the copper atom may also have an R group which includes an alkyl and/or aryl group. The alkyl and/or aryl group contains at least one electron-withdrawing substituent. The copper complex may likewise, as a mixed system, contain one or more types of carboxylic acid.

An electron-withdrawing substituent is understood in the present disclosure to mean a substituent which reduces the electron density in an atom bonded to the substituent compared to a configuration in which a hydrogen atom binds to the atom in place of the electron-withdrawing substituent.

An electron-withdrawing group may, for example, be selected from the following group: halogens, such as chlorine or especially fluorine, nitro groups, cyano groups or mixtures of these groups. The alkyl or aryl group may contain exclusively electron-withdrawing substituents, such as the electron-withdrawing groups mentioned, or hydrogen atoms.

When the ligand has an alkyl and/or aryl group having at least one electron-withdrawing substituent, the electron density at the copper atom(s) is reduced, as a result of which the Lewis acidity of the complex is increased.

The ligand may represent an anion of the carbonic acids CHalₓH₃₋ₓCOOH, especially CFₓH₃₋ₓCOOH and CClₓH₃₋ₓCOOH, where Hal is a halogen atom and x is an integer from 0 to 3. The ligand may also represent an anion of the carbonic acids CR′_{y}HalₓH_{3-x-y}COOH where Hal is a halogen atom, x is an integer from 0 to 3 and y is an integer at least having the value of 1. The remaining group R′ is an alkyl group, a hydrogen atom or an aromatic group, for example a phenyl group or all substituent groups described so far. It may contain electron-withdrawing substituents, especially the electron-withdrawing substituents described above. It may also contain a derivative of benzoic acid with an electron-withdrawing substituent. For example, the ligand may be an anion of carbonic acid R′—(CF₂)ₓ—CO₂H where n assumes an integer value from 1 to 20. For example, it is possible to use a fluorinated, especially a perfluorinated, homo- or heteroaromatic compound as the remaining group. One example is anions of fluorinated benzoic acid:

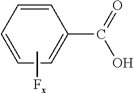

where x assumes an integer value from 1 to 5. More particularly, the following substituents, or those in which fluorine has been replaced by chlorine, may bind to the carboxyl group, all of these being strong Lewis acids:

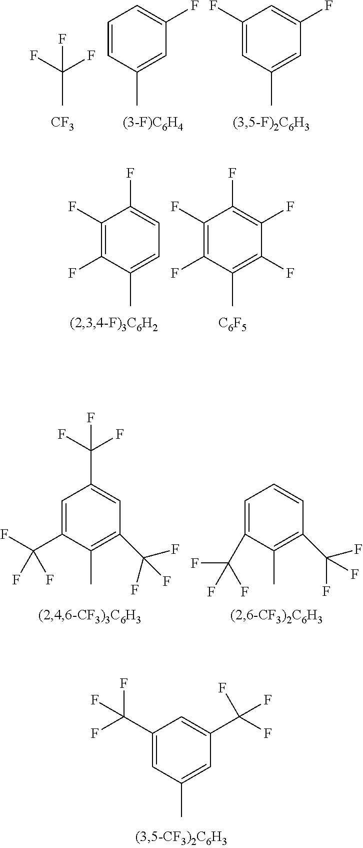

In addition, it is possible to use anions of the following acid as ligands:

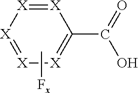

where X may be a nitrogen or carbon atom which binds, for example, to a hydrogen atom or a fluorine atom. By way of example, three of the X atoms may be a nitrogen atom and two may be a C—F bond or C—H bond (as triazine derivatives). It is also possible to use anions of the following acid as ligands:

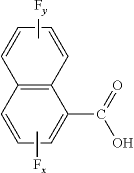

where the naphthyl ring is substituted by 1 to 7 fluorine substituents, such that y=0-4 and x=0-3, where y+x=1-7.

Fluorine and fluorine compounds as electron-withdrawing substituents are especially advantageous because copper complexes containing fluorine atoms, in the course of production of the optoelectronic component, can easily be vaporized and deposited in an organic layer. Further or alternative substituent groups may include a trifluoromethyl group.

Immediately atop the additional layer 510 may be applied a hole-transporting layer 512. Atop the hole-transporting layer 512 is applied a first active layer 514. The hole-transporting layer 512 serves for transport of holes injected from the anode 502 into the first active layer 514. It may include, for example, a p-doped conductive organic or inorganic material. For the p-doping, it is possible to use any suitable material. For example, the p-dopant used is a copper complex having at least one ligand having the chemical structure of the formula I:

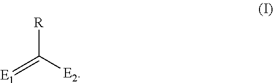

E₁ and E₂ are each independently one of the following elements: oxygen, sulfur or selenium. R is selected from the group of: hydrogen or substituted or unsubstituted, branched, linear or cyclic hydrocarbons.

Because the charge carrier transport in organic semiconductors does not take place in the conduction band but, for example, through hopping or tunneling operations, there are considerable differences in mobilities of holes and electrons. In order that exciton formation takes place not in the anode 502 but, for example, in the first active layer 514, an electron transport-blocking layer may additionally be provided between anode 502 and the first active layer 514.

The layer stack may also have a second active layer 516 which may be separated from the first active layer 514 by a charge generating layer sequence 100, 200, as has been described above in connection with FIG. 1 or FIG. 2, and which includes the process stabilization layer 510 (it may also be applied directly atop the first active layer 514). The second active layer 516 is screened from the cathode 504 by means of an electron-transporting layer 518. The electron-transporting layer 518 serves for the transport of electrons injected from the cathode 504 into the second active layer 516. It may include, for example, an n-doped conductive organic or inorganic material. In various working examples, the n-doped first organic semiconductor layer 102 may be applied atop the first active layer 514, and the second active layer 516 may be applied atop the process stabilization layer 510.

The charge generating layer sequence 100, 200 serves to provide additional charge carriers, by injecting holes in the direction of the cathode 504 and electrons in the direction of the anode 502. Between the charge generating layer sequence 100, 200 and the anode 504, more charge carriers are thus available to the first active layer 514. More charge carriers are likewise provided to the second active layer 516.

In the example of the OLED, both the first active layer 514 and the second active layer 516 are light-emitting layers. For this purpose, the first active layer 514 and the second active layer 516 each include an organic electroluminescent material, by means of which the formation of excitons from charge carriers and subsequent breakdown with emission of electromagnetic radiation is caused. The selection of the electroluminescent material is an area of constant further development. Examples of such organic electroluminescent materials include:
Poly(p-phenylenevinylene) and its derivatives substituted at different positions on the phenylene group;
(ii) Poly(p-phenylenevinylene) and its derivatives substituted at different positions on the vinylene group;
(iii) Poly(p-phenylenevinylene) and its derivatives substituted at different positions on the phenylene component and also at different positions on the vinylene group;
(iv) Polyarylenevinylene where the arylene may include such groups as, for instance naphthalene, anthracene, furylene, thienylene, oxadiazole, and the like;
(v) Derivatives of polyarylenevinylene where the arylene may be as in (iv) above and may additionally have substituents at different positions on the arylene;
(vi) Derivatives of polyarylenevinylene where the arylene may be as in (iv) above and may additionally have substituents at different positions on the vinylene;
(vii) Derivatives of polyarylenevinylene where the arylene may be as in (iv) above and may additionally have substituents at different positions on the arylene and substituents at different positions on the vinylene;
(viii) Copolymers of arylene-vinylene oligomers, for instance those in (iv), (v), (vi) and (vii) with nonconjugated oligomers; and
(ix) Poly(p-phenylene) and its derivatives substituted at different positions on the phenylene groups, including ladder polymer derivatives, for instance poly(9,9-dialkylfluorene) and the like;
(x) Polyarylenes where the arylene may include groups such as naphthalene, anthracene, furylene, thienylene, oxadiazole, and the like; and their derivatives substituted at different positions on the arylene group;
(xi) Copolymers of oligoarylenes, for instance those in (x) with nonconjugated oligomers;
(xii) Polyquinoline and its derivatives;
(xiii) Copolymers of polyquinoline with p-phenylene, substituted on the phenylene by, for example, alkyl groups or alkoxy groups, in order to acquire solubility; and
(xiv) Rigid rod polymers, for instance poly(p-phenylene-2,6-benzobisthiazole), poly(p-phenylene-2,6-benzobisoxazole), poly(p-phenylene-2,6-benzimidazole), and their derivatives.

Other organic emitting polymers, for instance those which use polyfluorene, include polymers which emit green, red, blue or white light, or their families, copolymers, derivatives or mixtures thereof. Other polymers include polyspirofluorene-like polymers.

Alternatively, rather than polymers, small organic molecules which emit via fluorescence or via phosphorescence may serve as the organic electroluminescent layer. Examples of small-molecule organic electroluminescent materials include:
(i) tris(8-hydroxyquinolinato)aluminum, (Alq);
(ii) 1,3-bis(N,N-dimethylaminophenyl)-1,3,4-oxidazole (OXD-8);
(iii) oxobis(2-methyl-8-quinolinato)aluminum;
(iv) bis(2-methyl-8-hydroxyquinolinato)aluminum;
(v) bis(hydroxybenzoquinolinato)beryllium (BeQ.sub.2);
(vi) bis(diphenylvinyl)biphenylene (DPVBI); and
(vii) arylamine-substituted distyrylarylene (DSA amine).

The first active layer 514 and the second active layer 516 may each be a white-emitting layer. This means that both the first active layer 514 and the second active layer 516 emit electromagnetic radiation over the entire visible spectrum. As a result of the stacking of two active layers, each of the first active layer 514 and the second active layer 516 needs only a low luminosity, in spite of which a high luminosity of the overall optoelectronic component 500 is achieved. It is particularly advantageous in this case that the p-doping of the charge transport layer 100, 200 arranged between the active layers and, for example, of the process stabilization layer 510 therein with the copper complex dopant has high transparency in the region of visible light. As a result, a high light yield from the optoelectronic component 500 is achieved.

The provision of the charge generating layer sequence 100, 200, through the injection of additional charge carriers into the adjoining active layers, increases the charge carrier density overall. Processes such as the formation or dissociation of charge carrier pairs or excitons, for example, are enhanced. Since some of the charge carriers are provided in the charge generating layer sequence 100, 200, i.e. in the optoelectronic component 500 itself, a low current density can be achieved at the anode 502 and the cathode 504.

The first active layer 514 and the second active layer 516 may also emit electromagnetic radiation in spectra shifted in respect to one another. For example, the first active layer 514 may emit radiation in a blue color spectrum, while the second active layer 516 emits radiation in a green and red color spectrum. Any other desired or suitable division is conceivable. It is especially advantageous in this context that a division can be made according to different physical and chemical properties of emitter materials. For example, one fluorescent emitter material or a plurality of fluorescent emitter materials may be incorporated in the first active layer 514, while one or more phosphorescent emitter materials are incorporated in the second active layer 516. The optional arrangement of the charge generating layer sequence 100, 200 already achieves a separation of the emitter materials. Through the separation of the emission spectra of the two active layers, it is also possible, for example, to establish a desired color locus of the optoelectronic component 500.

The function of the optional charge generating layer sequence 100, 200 can be described in an illustrative manner such that it connects a plurality of individual OLEDs in the form of the active layers in series. By virtue of the intrinsic provision of charge carriers, several photons can be emitted per charge carrier injected. Overall, in all embodiments, the current efficiency, i.e. the ratio of radiation emitted to electrical current introduced (cd/A) of the optoelectronic component 500, was much increased. Because it is possible to achieve high luminosity even with low currents in the electrodes, a particularly homogeneous illumination profile can be achieved in the case of large-area OLEDs. Advantageously, the lifetime of the first active layer 514 and of the second active layer 516 is also distinctly prolonged overall by virtue of low current densities and low evolution of heat. The cause of this aspect is the stacking of the active layers, which have to provide only a low luminance. An essential aspect for the stacking of active layers in a layer sequence is that sufficient charge carriers are provided by means of the optional charge generating layer sequence 100, 200, and that the absorption of the radiation emitted in the active layer 516 is substantially avoided through the use of the copper complex.

This applies not just to the field of use of the emitter devices, such as the OLED. In other working examples of the optoelectronic component 500, at least one of the first active layer 514 and the second active layer 516 may be a detector layer, for example a photovoltaic layer or a photodetector. In the case of a hybrid system in which, for example, the first active layer 514 is an emitting layer and the second active layer 516 a detecting layer, it is conceivable that the second active layer 516 detects electromagnetic radiation in a wavelength range by virtue of a small proportion, if any, of electromagnetic radiation being emitted by the first active layer 514. It is likewise conceivable that the second active layer 516 in the manner of a detector detects radiation specifically in a region of the emission wavelengths of the first active layer 514.

Overall, specifically the structure gives an optoelectronic component having an optional charge generating layer sequence 100, 200 containing the copper complex the possibility of providing particularly efficient optoelectronic components.

FIG. 6 shows the schematic diagram of another working example of an optoelectronic component 600.

In this case, the other working example differs from the working example of FIG. 5 in the layer sequence between the anode 502 and the cathode 504. The layer stack of the working example shown in FIG. 6 has a second charge generating layer sequence 602 and a third active layer 604 arranged between the second active layer 516 and the electron-transporting layer 518.

The optoelectronic component 600 thus has a stack structure composed of three active layers. The stack structure (or stacked device) may also include further stacks composed of a charge generating layer sequence and an active layer. In principle, it is conceivable to provide a structure with any number of stacks. A stack structure with two active layers is also referred to, for example, as a tandem structure. Similar structures are known per se, for example, from document [3] or document [4], which are hereby incorporated by reference into the disclosure of the present application.

The stack structure is especially suitable for providing an OLED which emits white light. In this context, the design with three different stacks, as in the case of the third working example, is particularly advantageous. For example, it is possible to provide what is called an “RGB emitter” in which one active layer in each case emits a red, green or blue color spectrum. It is thus possible to establish an exact color locus of the spectrum emitted overall. By virtue of the division into three active layers, it is possible, for example, for any emitter material used to be introduced into an optical optimal position within the layer stack. This can take account of effects such as absorption of different wavelengths or refractive indices at interfaces.

It will be appreciated that the above statements also apply analogously to an optoelectronic device 600 in which at least one of the active layers acts as a detector.

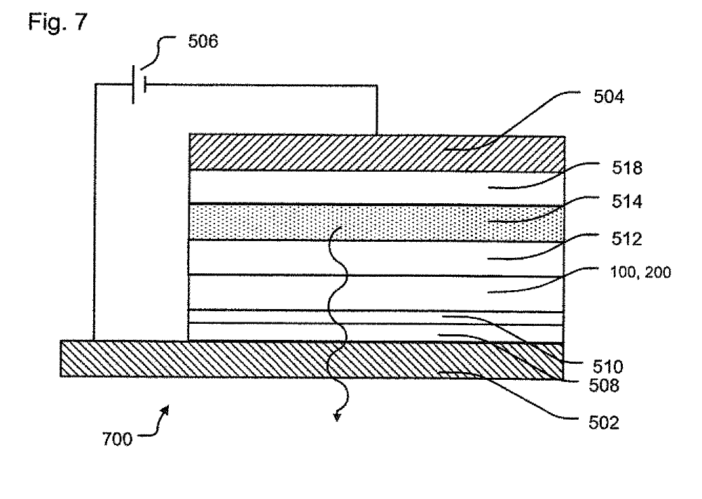

FIG. 7 shows the schematic diagram of yet another working example of an optoelectronic component 700 with a charge generating layer sequence 100, 200. The working example of an optoelectronic component 700 shown in FIG. 7 differs from the working example of an optoelectronic component 500 shown in FIG. 5 merely in that an active layer has been provided. The latter is arranged between the electron-transporting layer 518 and the hole-transporting layer 512. The charge generating layer sequence 100, 200 has been arranged between the anode 502 and the hole-transporting layer 512.

Through the arrangement of the charge generating layer sequence 100, 200 at the anode 502, it is more easily possible to introduce charge carriers, i.e. especially holes, into the layer stack. This is particularly suitable for suppressing effects resulting from a work function of the anode material, which may in some cases lead to inhibition of the transport of holes into the layer stack. The charge generating layer sequence 100, 200 thus does not have the effect of providing additional charge carriers in the layer stack. Instead, it promotes, for example, the entry of charge carriers from metallic electrodes into organic materials in the layer stack. This function of the charge generating layer sequence 100, 200 can also be used in combination with the arrangements of the optoelectronic component in the working example shown in FIG. 5 or that shown in FIG. 6, or in any other embodiments.

The inventors have examined which specific material is the most suitable as a matrix for the p dopant with the above-specified copper complex. For this purpose, hole-only devices in which Cu(I) pFBz was covaporized with various matrix materials were processed. The highest electrical conductivities at minimum dopant concentration in the process stabilization layer were measured in the matrix HTM-014 from Merck.

In addition, this combination (HTM-014 and Cu(I) pFBz) was tested as a process stabilization layer in a white-emitting OLED corresponding to the current state of development. Compared to the OLED used to date, a distinctly improved service life was found for virtually identical voltage and efficiency values.

The optoelectronic component was described using some working examples to illustrate the underlying concept. These working examples are not restricted to particular combinations of features. Even if some features and configurations have been described only in connection with a particular working example or individual working examples, they may each be combined with other features from other working examples. It is likewise possible to omit or add individual features described or particular configurations in the working examples, provided that the general technical teaching is still implemented.

While the disclosed embodiments has been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

### LIST OF REFERENCE NUMERALS

Charge generating layer sequence 100
First organic semiconductor layer 102
Second organic semiconductor layer 104
Interface 106
Charge carrier pair 108
Charge generating layer sequence 200
Interlayer 202
Diagram 300
LUMO energy level 302
HOMO energy level 304
Optoelectronic component 500
Anode 502
Cathode 504
Power source 506
Wet-chemically processed hole injection layer 508
Process stabilization layer 510
Hole-transporting layer 512
First active layer 514
Second active layer 516
Electron-transporting layer 518
Optoelectronic component 600
Second charge generating layer sequence 602
Third active layer 604
Optoelectronic component 700
Electrical field E

1. An optoelectronic component comprising:
a wet-chemically processed hole injection layer; and
an additional layer doped with a dopant and adjacent to the wet-chemically processed hole injection layer, the dopant comprising a copper complex having at least one ligand with the chemical structure according to formula I: 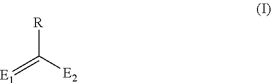
in which E₁ and E₂ are each independently one of the following elements: sulfur, oxygen or selenium, and R is selected from the group of: hydrogen or substituted or unsubstituted, branched, linear or cyclic hydrocarbons.

2. The optoelectronic component as claimed in claim 1,
wherein the copper complex is a copper(I) pentafluorobenzoate.

3. The optoelectronic component as claimed in claim 1,
wherein the copper complex has been introduced as a dopant in a matrix material.

4. The optoelectronic component as claimed in claim 3,
wherein the matrix material comprises 1-TNATA (4,4′,4″-tris(N-(1-naphthyl)-N-phenylamino)triphenylamine.

5. The optoelectronic component as claimed in claim 1, further comprising:
an organic layer structure for separation of charge carriers of a first charge type and charge carriers of a second charge type.

6. The optoelectronic component as claimed in claim 5,
wherein the organic layer structure is a charge generating layer sequence.

7. The optoelectronic component as claimed in claim 5,
wherein the organic layer structure includes an n-doped organic semiconductor layer.

8. The optoelectronic component as claimed in claim 7,
wherein a nonconductive interlayer is arranged between the hole injection layer and the n-doped organic semiconductor layer.

9. The optoelectronic component as claimed in claim 8,
wherein the hole injection layer has a doping gradient toward the n-doped organic semiconductor layer.

10. The optoelectronic component as claimed in claim 9,
wherein the doping of the hole injection layer increases toward the n-doped organic semiconductor layer.

11. The optoelectronic component as claimed in claim 6,
comprising a layer stack including the organic layer structure.

12. The optoelectronic component as claimed in claim 11,
wherein the layer stack includes at least one active layer.

13. The optoelectronic component as claimed in claim 12,
wherein the active layer includes an electroluminescent material.

14. The optoelectronic component as claimed in claim 12,
wherein the organic layer structure is arranged between a first active layer and a second active layer.

15. The optoelectronic component as claimed in claim 10,
wherein the organic layer structure has been applied to an electrode.

16. An use of a copper complex as a dopant for doping a layer arranged adjacent to a wet-chemically processed hole injection layer, wherein the copper complex has at least one ligand with the chemical structure according to formula I: 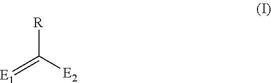
in which E₁ and E₂ are each independently one of the following elements: sulfur, oxygen or selenium, and R is selected from the group of: hydrogen or substituted or unsubstituted, branched, linear or cyclic hydrocarbons.

17. The optoelectronic component as claimed in claim 10,
wherein the organic layer structure has been applied to an anode contact.
